(19) United States
(12) Patent Application Publication
(10) Pub. No.: US 2025/0266752 A1
(43) Pub. Date: Aug. 21, 2025

(54) GATE DRIVER FOR HYBRID POWER SWITCHES

(71) Applicant: TEXAS INSTRUMENTS INCORPORATED, Dallas, TX (US)

(72) Inventors: Thomas LaBella, Raleigh, NC (US); Wei Zhang, Plano, TX (US); Aswin Srinivasa Rao, San Jose, CA (US)

(21) Appl. No.: 18/650,533

(22) Filed: Apr. 30, 2024

Related U.S. Application Data
(60) Provisional application No. 63/554,287, filed on Feb. 16, 2024.

(51) Int. Cl. H02M 1/088

(52) U.S. Cl. CPC H02M 1/088

(57) ABSTRACT

A method includes receiving a signal to turn on a hybrid power switch circuitry when the received signal is asserted. The method further includes generating a first logic signal in response to a feedback signal and further in response to a signal received from one or more switches. The method also includes generating a second logic signal in response to the feedback signal and further in response to the signal received from the one or more switches. The method includes driving a silicon device based on the first logic signal. Moreover, the method includes driving a wide bandgap device based on the second logic signal. The method includes generating the feedback signal based on whether the silicon device or the wide bandgap device is on or off.

### RELATED APPLICATIONS

The instant application claims the benefit and priority to the U.S. Provisional Application No. 63/554,287 that was filed on Feb. 16, 2024, which is incorporated herein by reference in its entirety.

### BACKGROUND

High power applications have increased in recent years. For example, increasing number of electric vehicles has resulted in an increased number of high-power applications such as main power switches in electric vehicle inverters. Silicon based transistors such as insulated-gate bipolar transistors (IGBT) have traditionally been used but have significant power loss. Wide bandgap (WBG) devices such as silicon carbide have a higher efficiency in comparison to IGBT devices but are more expensive. Some applications use a hybrid approach that includes both an IGBT device and a WBG device to achieve a similar efficiency as a pure WBG device but with reduced cost. However, the hybrid approach increases the computational complexity and processing cost because the timing requirement to turn the IGBT and WBG devices on/off at the appropriate time.

### SUMMARY

In an example, an apparatus includes one or more programmable switches, a logic circuitry, a driver circuitry, a hybrid power switch circuitry, and a detection circuitry. The one or more programmable switches after programming, turn on a first device and a second device within the hybrid power switch circuitry based on a selected ratio of the first device to the second device and further when a received signal to turn on the hybrid power switch circuitry is asserted. The first device is a device with a first type and the second device is a device with a second type. The logic circuitry is coupled to the one or more programmable switches that generates a logic signal to turn a driver circuitry on or off. The logic signal is generated based on a signal received from the one or more programmable switches and further based on a detection signal received from the detection circuitry. The driver circuitry is coupled to the logic circuitry. The driver circuitry generates a driving signal to the hybrid power switch circuitry and the detection circuitry based on the logic signal. The hybrid power switch circuitry includes the first device and the second device. The hybrid power switch circuitry receives the driving signal that controls a timing of turning the first device and the second device on and off. The detection circuitry receives a feedback signal associated with the hybrid power switch circuitry. The detection circuitry detects whether the second device is on or off and further whether the first device is on or off. The detection circuitry generates the detection signal to the logic circuitry.

In at least one example, an apparatus includes one or more programmable switches, a first logic circuit, a second logic circuit, a first driving circuit, a second driving circuit, and a feedback circuitry. The one or more programmable switches after programming turn on a wide bandgap device and a silicon device within a hybrid power switch circuitry based on a selected ratio of the silicon device to the wide bandgap device and further when a received signal to turn on the hybrid power switch circuitry is asserted. The first logic circuit is coupled to the one or more programmable switches. The first logic circuit generates a first logic signal. The first driving circuit is coupled to the first logic circuit to receive the first logic signal and in response thereto drive the silicon device of the hybrid power switch circuitry. The second logic circuit is coupled to the one or more programmable switches. The second logic circuit generates a second logic signal. The second driving circuit is coupled to the second logic circuit to receive the second logic signal and in response thereto drive the wide bandgap device of the hybrid power switch circuitry. The feedback circuitry receives a feedback signal associated with the hybrid power switch circuitry. The feedback circuitry generates a feedback signal based on an on/off status of the silicon device or the wide bandgap device. The feedback circuitry sends the feedback signal to the first logic circuit and the second logic circuit. The first logic circuit generates the first logic signal based on the feedback signal and further based on a signal received from the one or more programmable switches. The second logic circuit generates the second logic signal based on the feedback signal and further based on the signal received from the one or more programmable switches.

In at least one example, a method includes receiving a signal to turn on a hybrid power switch circuitry when the received signal is asserted. The method also includes generating a first logic signal in response to a feedback signal and further in response to a signal received from one or more switches. Moreover, a second logic signal is generated in response to the feedback signal and further in response to the signal received from the one or more switches. A silicon device is driven based on the first logic signal. A wide bandgap device is driven based on the second logic signal. The feedback signal is generated based on whether the silicon device or the wide bandgap device is on or off.

### BRIEF DESCRIPTION OF THE DRAWINGS

FIG. 1 is a schematic diagram of an apparatus including a gate driver for hybrid power switches, in an example.

FIG. 2 is a schematic diagram of another apparatus including a gate driver for hybrid power switches, in an example.

FIG. 3 is a schematic diagram of a set and reset logic circuitry, in an example.

FIG. 4 is a timing diagram of the apparatus in FIG. 2, in an example.

FIG. 5 is a waveform of timing simulation of an apparatus, in an example.

FIG. 6 is a simulation for an energy loss of an apparatus, in an example.

FIG. 7 is a flowchart illustrating operation of an apparatus with a gate driver for hybrid power switches, in an example.

### DETAILED DESCRIPTION

The same reference numbers or other reference designators are used in the drawings to designate the same or similar (either by function and/or structure) features. Hybrid power switches have been used in high-power applications, such as traction inverters used in electric vehicles that convert a direct current (DC) supply from the vehicle's battery into alternating current (AC) output, high-power industrial motor drives, solar inverters and energy storage in solar power applications, etc. For example, a first device type such as a wide-bandgap device may be used in parallel with a second device type such as a silicon device, e.g., IGBT device, to reduce cost associated with use of a pure WBG device and resulting in significant power loss improvement over use of a pure silicon device.

Gate timing between a WBG device and a silicon device is important to improve efficiency. Some approaches have controlled the gate timing between a WBG device and a silicon device by using a microcontroller or other similar components, which leads to added complexity and cost such as higher silicon use, higher pin count, burdening the microcontroller with processing associated with the timing need in real time, etc. In certain cases, the gate timing has been controlled using register settings that are programmed and changed on the fly or alternatively separate gate drivers have been used to control the silicon device and the WBG device separately with their own gate signal timings. In other words, there is a tradeoff between the size of the device, the cost, the complexity of implementation, and efficiency.

According to one example, the gate timing between a WBG device and a silicon device is controlled by using a feedback signal associated with the hybrid power switches, enabling the gate driver to improve the timing between the WBG device and the silicon device in order to improve efficiency. As such, use of a microcontroller to control the gate timing between the WBG device and the silicon device is eliminated, which reduces the computational burden on the microcontroller as well as reducing the pin count and die area of the gate driver. Furthermore, controlling the gate timing using a feedback signal is performed automatically and results in high efficiency at reduced cost (e.g., smaller die size, reduced number of pin counts of gate driver, etc.).

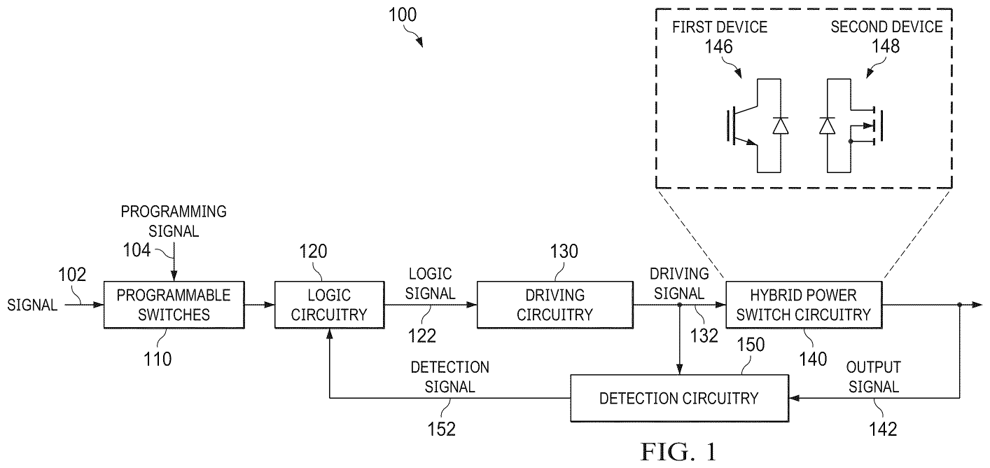

FIG. 1 is a schematic diagram of an apparatus 100 including a gate driver for hybrid power switches 140, in an example. The apparatus 100 includes a set of programmable switches 110, a logic circuitry 120, a driving circuitry 130, a hybrid power switch circuitry 140, and a detection circuitry 150. According to one example, the programmable switches 110 are coupled to the logic circuitry 120 that is coupled to the driving circuitry 130 that is coupled to the hybrid power switch circuitry 140 that is coupled to the detection circuitry 150.

The hybrid power switch circuitry 140 may include a first device 146 (switch) being a first type, e.g., a silicon type device such as an IGBT switch, and a second device 148 (switch) being a second type, e.g., a WBG device such as a silicon carbide switch. In this example, the first device 146 is coupled to the second device 148 in parallel.

According to some examples, replacing a small portion of a pure silicon device, in a high-power switch circuitry, with a WBG device results in the hybrid power switch circuitry with an increased efficiency and reduced cost, as described above. Similarly, replacing a portion of a pure WBG device, in a high-power switch circuitry, with a silicon device results in the hybrid power switch circuitry with an improved efficiency, at a reduced cost and smaller die size and reduced pin counts, etc. For illustrative purposes, in the example of FIG. 1, a small portion of a pure silicon device is replaced with a WBG device to form the hybrid power switch circuitry 140.

In one example, the programmable switches 110 may include a plurality of switches that may be set or programmed by a customer, e.g., electric vehicle manufacturer, solar power manufacturer, etc. For example, the programmable switches 110 may be programmed once using a programming signal 104. Programming the programmable switches 110 once is for illustrative purposes and should not be construed as limiting the scope of the examples.

According to one example, programming the programmable switches 110 may be based on a ratio of a device of a first type, e.g., a silicon device such as an IGBT switch, to a device of a second type, e.g., a WBG device such as a WBG switch, in the hybrid power switch circuitry 140. In this example, since a small portion of a silicon device is replaced with a WBG device, the ratio of silicon device to a WBG device has a higher ratio. The higher ratio may be used to program the programmable switches 110 via the programming signal 104.

According to some examples, a silicon device such as an IGBT switch reacts slower, e.g., turns off slower, in comparison to a WBG device, e.g., a WBG switch. As such, the higher ratio of a silicon device to a WBG device may be used to improve efficiency and to reduce loss. For example, during turning on/off the hybrid power switch circuitry 140, the device with a higher ratio (here and for illustrative purposes a silicon device) is to be turned on/off before (e.g., prior to) turning on/off the device with a lower ratio (here for illustrative purposes a WBG device). In contrast and for illustrative purposes, in a hybrid power switch circuitry 140 with a higher ratio of a WBG device to a silicon device, the WBG device is turned on/off before (e.g., prior to) turning the silicon device on/off in order to improve efficiency and to reduce loss. Programming the programmable switches 110 based on the ratio of the device type in the hybrid power switch circuitry 140 results in the full load of current being carried by the higher ratio device type during turn-on by turning on the device type with a higher ratio prior to turning on the device type with a lower ratio. According to an example, turn-on is when a device is being placed from a power off position to a power on position. During turn-off, the hybrid power switch circuitry 140, turns off the device type with the higher ratio, e.g., a silicon device such as an IGBT switch in this example, before (e.g., prior to) turning off the device type with a lower ratio reduces (voltage current) VI overlap turn off loss, thereby increasing the efficiency.

Once programmed, the programmable switches 110 may receive a signal 102 to turn the hybrid power switch circuitry 140 on or off, as needed. In one example, the signal 102 may be a pulse width modulation signal that is received from a controller, e.g., a microcontroller unit. The signal 102 is routed through the programmable switches 110 based on the ratio of device types in the hybrid power switch circuitry 140, as described above, such that a device type within the hybrid power switch circuitry 140 with a higher ratio is turned on first before turning on a device type with a lower ratio within the hybrid power switch circuitry 140. The logic circuitry 120 receives the signal 102 routed through the programmable switches 110 and generates a logic signal 122. The logic signal 122 may include one or more signals to set or reset in order to enable or disable a particular device type within the hybrid power switch circuitry 140. In other words, the logic signal 122 controls the chronological ordering to turn a particular device type within the hybrid power switch circuitry 140 on/off.

In one example, the logic signal 122 is received by the driving circuit 130 and generates a driving signal 132. The driving signal 132 drives the device types within the hybrid power switch circuitry 140 based on the received logic signal 122. The driving signal 132 is sent to the hybrid power switch circuitry 140, thereby turning devices, e.g., first device 146 and second device 148, within the hybrid power switch circuitry 140 on/off based on their type. For example, the driving signal 132 may turn on the first device 146 when the signal 102 is asserted high before turning on the second device 148. Similarly, the driving signal 132 may turn off the first device 146 before turning off the second device 148 when the signal 102 is asserted low.

According to one example, the detection circuitry 150 receives one or more signals associated with the hybrid power switch circuitry 140. For example, the driving signal 132 may be sent to the detection circuitry 150 and may include the gate voltage feedback. Moreover, the output signal 142 from the hybrid power switch circuitry 140 may be sent to the detection circuitry 150 and may include the drain-source (or collector-emitter) voltage feedback. The detection circuitry 150 may use the driving signal 132 and/or the output signal 142 to determine whether the second device 148 is to be turned on (during powering on of the hybrid power switch circuitry 140). For example, the detection circuitry 150 may determine whether the first device 146 is on and if so to generate a detection signal 152 to turn on the second device 148 during powering on of the hybrid power switch circuitry 140. As such, the full load current is carried by the first device 146 that has a higher ratio in comparison to the second device 148. Moreover, the detection circuitry 150 may use the driving signal 132 and/or the output signal 142 to determine whether the second device 148 is to remain on when the first device 146 is turning off. For example, the detection circuitry 150 may determine that the first device 146 is not off and therefore may generate the detection signal 152 to maintain the second device 148 on until the first device 146 is off before the second device 148 is turned off. As such, voltage-current (VI) overlap turn off loss is reduced.

Accordingly, turning devices on/off within the hybrid power switch circuitry 140 based on the device type during powering the hybrid power switch circuitry 140 on/off is controlled automatically through a feedback signal rather than using a microcontroller. In other words, the gate timing between a WBG device and a silicon device is controlled by using a feedback signal associated with the hybrid power switch circuitry 140.

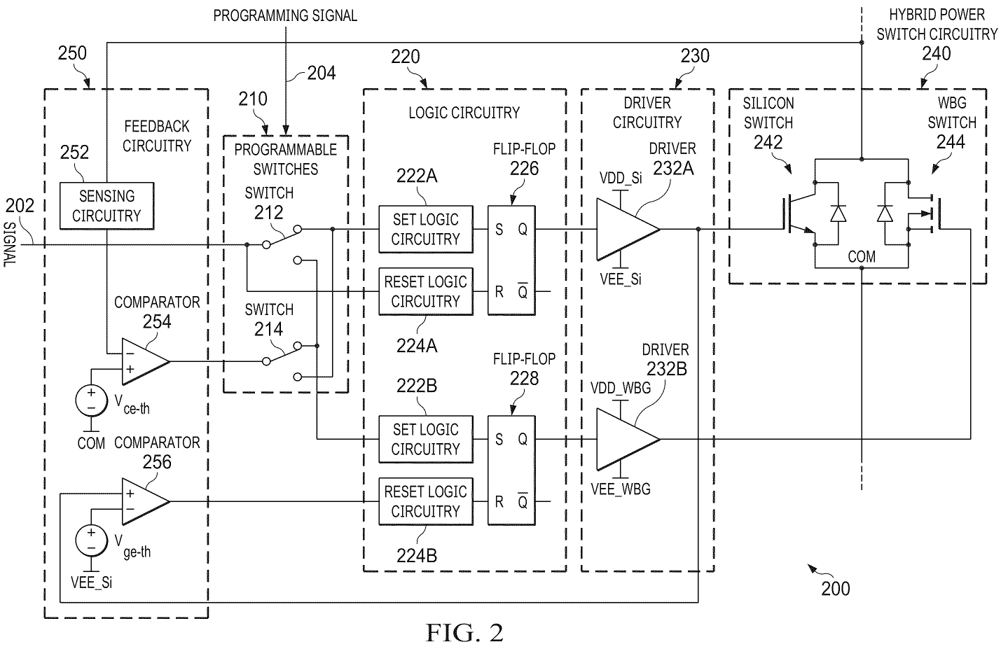

FIG. 2 is a schematic diagram of another apparatus 200 including a gate driver for hybrid power switches, in an example. Apparatus 200 includes programmable switches 210 coupled to a logic circuitry 220 coupled to a driver circuitry 230 coupled to a hybrid power switch circuitry 240 coupled to a feedback circuitry 250. The programmable switches 210 are similar to the programmable switches 110 of FIG. 1 and operate similar to the programmable switches 110. The logic circuitry 220 is similar to the logic circuitry 120 of FIG. 1 and operates similar to the logic circuitry 120. The driving circuitry 230 is similar to the driving circuitry 130 of FIG. 1 and operates similar to the driving circuitry 130. The hybrid power switch circuitry 240 is similar to the hybrid power switch circuitry 140 of FIG. 1 and operates similar to the power switch circuitry 140. The hybrid power switch circuitry 240 includes two device types that are connected in parallel to one another. The first device type may be a silicon switch 242 and the second device type may be a WBG switch 244. Similar to FIG. 1, the ratio of the silicon switch 242 to the WBG switch 244 is higher for illustrative purposes. The feedback circuitry 250 is similar to the detection circuitry 150 of FIG. 1 and operates similar to the detection circuitry 150. Signal 202 is similar to signal 102.

The programmable switches 210 include switches 212 and 214 in one example for illustrative purposes. In another example, more than two switches in a different configuration may be used. The programmable switch 210 receives a programming signal 204, e.g., from a customer, to program the switches 212 and 214 (e.g., positioning the switches 212 and 214). The programming signal 204 may be similar to the programming signal 104. In this example, the switch 212 is switched to a positioned to cause the silicon switch 242 to turn on before turning on the WBG switch 244 in order to cause the full load to be carried by the silicon switch 242 when turning on the hybrid power switch circuitry 240 because the silicon switch 242 in the hybrid power switch circuitry 240 has a higher ratio in comparison to the WBG switch 244. The switch 214 is switched to a position to cause the WBG switch 244 to remain on when turning off the hybrid power switch circuitry 240 until the silicon switch 242 is turned off completely in order to reduce the VI overlap turn off loss since the silicon switch 242 is the hybrid power switch circuitry 240 has a higher ratio in comparison to the WBG switch 244.

The logic circuitry 220 may include a set of set and reset logic circuitries as well as a set of flip-flops. In one example, the logic circuitry 220 may include a set logic circuitry 222A coupled to a set input of a flip-flop 226 circuitry to cause the silicon switch 242 to turn on based on the signal 202 being asserted high when routed through the programmable switches 210 and further based on a feedback signal received from the feedback circuitry 250. In other words, the set logic circuitry 222A in combination with the set input of the flip-flop 226 circuitry generates a set signal to turn on the silicon switch 242 based on the signal 202 being asserted high and as routed through the programmable switches 210 and further based on a feedback signal received from the feedback circuitry 250. In one example, the logic circuitry 220 may include a reset logic circuitry 224A coupled to a reset input of a flip-flop 226 circuitry to cause the silicon switch 242 to turn off based on the signal 202 being asserted low when routed through the programmable switches 210 and further based on a feedback signal received from the feedback circuitry 250. In other words, the reset logic circuitry 224A in combination with the reset input of the flip-flop 226 circuitry generate a reset signal to turn off the silicon switch 242 off based on the signal 202 being asserted low and as routed through the programmable switches 210 and further based on a feedback signal received from the feedback circuitry 250.

In one example, the logic circuitry 220 may include a set logic circuitry 222B coupled to a set input of a flip-flop 228 circuitry to cause the WBG switch 244 to turn on based on the signal 202 being asserted high when routed through the programmable switches 210 and further based on a feedback signal received from the feedback circuitry 250 (e.g., after the silicon switch 242 is turned on in order to cause the full load to be carried by the silicon switch 242 since the silicon switch 242 has a higher ratio to the WBG switch 244). In other words, the set logic circuitry 222B in combination with the set input of the flip-flop 228 circuitry generates a set signal to turn on the WBG switch 244 on based on the signal 202 being asserted high and as routed through the programmable switches 210 and further based on a feedback signal received from the feedback circuitry 250. In one example, the logic circuitry 220 may include a reset logic circuitry 224B coupled to a reset input of a flip-flop 228 circuitry to cause the WBG switch 244 to turn off based on the signal 202 being asserted low when routed through the programmable switches 210 and further based on a feedback signal received from the feedback circuitry 250 (e.g., the WBG switch 244 is kept on to reduce the VI overlap turn off loss until the silicon switch 242 is turned off). In other words, the reset logic circuitry 224B in combination with the reset input of the flip-flop 228 circuitry generates a reset signal to turn off the WBG switch 242 off based on the signal 202 being asserted low and as routed through the programmable switches 210 and further based on a feedback signal received from the feedback circuitry 250.

In one example, the logic signal generated by the logic circuitry 220 is sent to the driving circuitry 230. The driving circuitry 230 may include a driver 232A for driving the silicon switch 242 on/off based on the received logic signal from the logic circuitry 220. For example, the driver 232A may drive the voltage to VDD_Si to turn on the silicon switch 242 in response to the logic signal received from the logic circuitry 220. In contrast, the driver 232A may drive the voltage to VEE_Si to turn off the silicon switch 242 in response to the logic signal received from the logic circuitry 220. In one example, the driving circuitry 230 may further include a driver 232B for driving the WBG switch 244 on/off based on the received logic signal from the logic circuitry 220. For example, the driver 232B may drive the voltage to VDD_WBG to turn on the WBG switch 244 in response to the logic signal received from the logic circuitry 220. In contrast, the driver 232B may drive the voltage to VEE_WBG to turn off the WBG switch 244 in response to the logic signal received from the logic circuitry 220.

In one example, one or more signals associated with the hybrid power switch circuitry 240 is transmitted as a feedback signal to the feedback circuitry 250. The feedback circuitry 250 may include a sensing circuitry 252, a comparator 254, and a comparator 256. In this example, the drain-source (or collector-emitter) voltage of the hybrid power switch circuitry 240 is sent as a feedback signal to the feedback circuitry 250 to determine whether the silicon switch 242 is turned on, via the sensing circuitry 252. The sensing circuitry 252 may output a voltage to the comparator 254 that compares the output voltage to a ground voltage to determine whether the silicon switch 242 is turned on, thereby carrying full load. If the silicon switch 242 is turned on it is carrying full load and since the ratio of silicon switch 242 to the WBG switch 244 is high then to improve efficiency the WBG switch 244 can be turned on. As such, the output of the comparator 254 is input to the set logic circuitry 222B to turn on the WBG switch 244 if the silicon switch 242 is turned on. However, if the output of the sensing circuitry 252 is low then the output of the comparator 254 is asserted low and therefore the set logic circuitry 222B does not generate a signal asserted high to cause the WBG switch 244 to turn off and remains in an off position.

In one example, the signal on the gate of the silicon switch 242 (e.g., driving signal for driving the silicon switch 242) may be sent to the feedback circuitry 250 where the signal is compared to VEE_Si via the comparator 256 to determine whether the silicon switch 242 is on or off. If the silicon switch 242 is not off yet, then the WBG switch 244 is maintained in an on position in order to reduce VI overlap turn off loss. However, if the silicon switch 242 is determined to be off (e.g., no voltage on its gate), then the WBG switch 244 can be turned off. As such, the output of the comparator 256 generates a signal to cause the reset logic circuitry 224B to generate an asserted high signal for the reset input of flipflop 228 to cause the driver 232B to drive the WBG switch 244 low or turn off.

Accordingly, the silicon device is turned on during the rising edge of the pulse width modulation signal and turned off during the falling edge of the pulse width modulation signal. Moreover, the collector voltage falling turns on the WBG device whereas the falling voltage of the gate for the silicon device turns off the WBG device.

Accordingly, a dual output gate driver, as described, adapts the timing between the gate waveforms of the parallel silicon device and the WBG device using the feedback signal from the switch node and the gate voltage. The gate driver optimizes the timing to turn the switches on/off to achieve higher efficiency, thereby eliminating the need to control the timing using a microcontroller. In other words, the chronological ordering of turning the silicon device and the WBG device is controlled using the feedback signal rather than using a microcontroller. As such, the computational cost and burden on the microcontroller is reduced while reducing the pin counts and die area of the gate drivers.

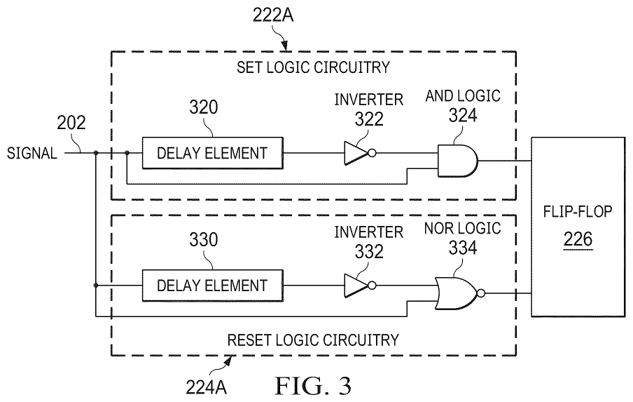

FIG. 3 is a schematic diagram of a set and reset logic circuitry, in an example. The set logic circuitry 222A may include a delay element 320 coupled to an inverter 322 coupled to an AND logic 324. The signal 202 is sent to one input of the AND logic 324 while the signal 202 is sent through the delay element 320 coupled to the inverter 322 and coupled to a second input of the AND logic 324. The output of the AND logic 324 may be coupled to a set input of the flipflop 226. The reset logic circuitry 224A may include a delay element 330 coupled to an inverter 323 coupled to a NOR logic 334. The signal 202 is sent to one input of the NOR logic 334 while the signal 202 is sent through the delay element 330 coupled to the inverter 332 and coupled to a second input of the NOR logic 334. The output of the NOR logic 334 may be coupled to a reset input of the flipflop 226.

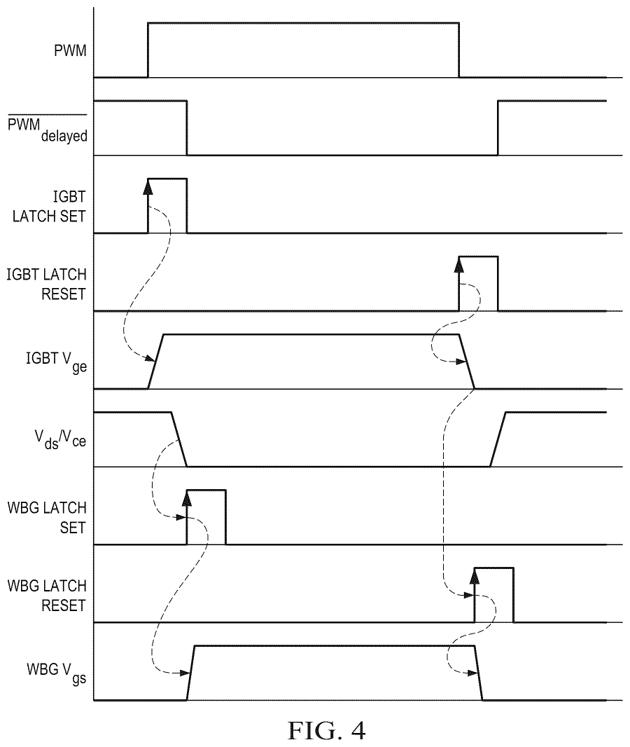

FIG. 4 is a timing diagram of the apparatus in FIG. 2, in an example. A pulse width modulation (PWM) is shown. When the PWM signal goes high, the inversion of the PWM signal after a delay goes low. The PWM signal asserting high causes the set input of the set logic circuitry 222A to be asserted high (e.g., IGBT latch set). As such, the output of the driver 232A is asserted high causing the silicon device 242, e.g., IGBT, to turn on such that the IGBT voltage gate to emitter (V_{ge}) goes high. The output of the hybrid power switch circuitry 240 is compared to a ground voltage by the comparator 254, e.g., voltage of drain to source to voltage of collector to emitter (V_{ds}/V_{ce}). The output of the comparator 254 causes the set input of the flipflop 228 (e.g., WBG latch set) to be set high by the set logic circuitry 222B when the silicon device 242 is turned on. As such, the driver 232B drives the WBG device 244 to turn on as shown by WBG V_{gs}.

After a certain amount of time, the PWM signal may be deasserted. When the PWM signal goes low, the inversion of the PWM signal after a delay goes high. The PWM signal asserting low causes the reset input of the reset logic circuitry 224A to be asserted high (e.g., IGBT latch reset). As such, the output of the driver 232A is asserted low causing the silicon device 242, e.g., IGBT, to turn off, e.g., IGBT V_{ge} goes low. The output of the hybrid power switch circuitry 240 is compared to a ground voltage by the comparator 256, e.g., voltage of drain to source to voltage of collector to emitter (V_{ds}/V_{ce}). The output of the comparator 256 causes the reset input of the flipflop 228 (e.g., WBG latch reset) to be set high by the reset logic circuitry 224B when the silicon device 242 is turned off. As such, the driver 232B drives the WBG device 244 to turn off as shown by WBG V_{gs}.

As illustrated, the apparatus 200 is programmed via the programmable switches 210 according to the ratio of silicon switch to the WBG switch. In one example, since the silicon switch reacts slower in comparison to the WBG switch and because the ratio of the silicon switch to the WBG switch is higher, then the programmable switches 210 are programmed to turn the silicon switch on/off before turning the WBG switch on/off. Such programming during turning on the hybrid power switch circuitry enables the silicon switch that has a higher ratio than the WBG switch to carry the full load. Moreover, such programming during turn-off of the hybrid power switch circuitry enables the WBG switch to remain on until the silicon switch is turned off to reduce VI turnover loss.

According to some examples, the programmable switches may be programmed differently from the one described in FIGS. 1-3. In other words, specific programming of the programmable switches and configuration of the logic circuitry has been provided for illustrative purposes and should not be construed as limiting the scope of the examples.

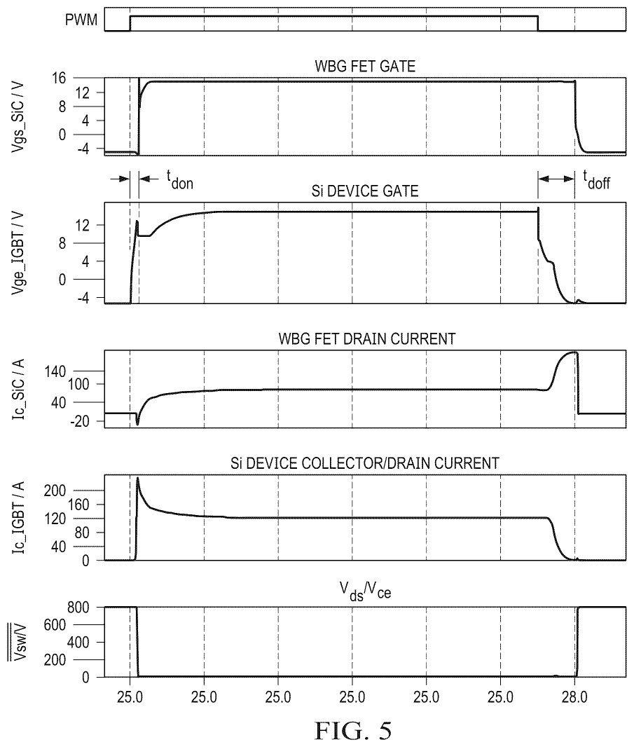

FIG. 5 is a waveform of timing simulation of an apparatus, in an example. The simulation illustrates voltage on the gate of the WBG device and a silicon device. The simulation illustrates an increase in WBG drain current when the current of the collector/drain of the silicon device decreases. As such, voltage of the drain/source to collector/emitter is reduced, thereby reducing the VI overlap loss. According to one example, the architecture of FIGS. 1-4, adapts the relative delay times between the silicon device and WBG device automatically (without using the microcontroller) based on the collector (or drain) voltage and gate voltage of the silicon device, thereby improving efficiency and reducing computational cost and complexity at a smaller dies size, reduce pin input, lower gate drive cost, etc.

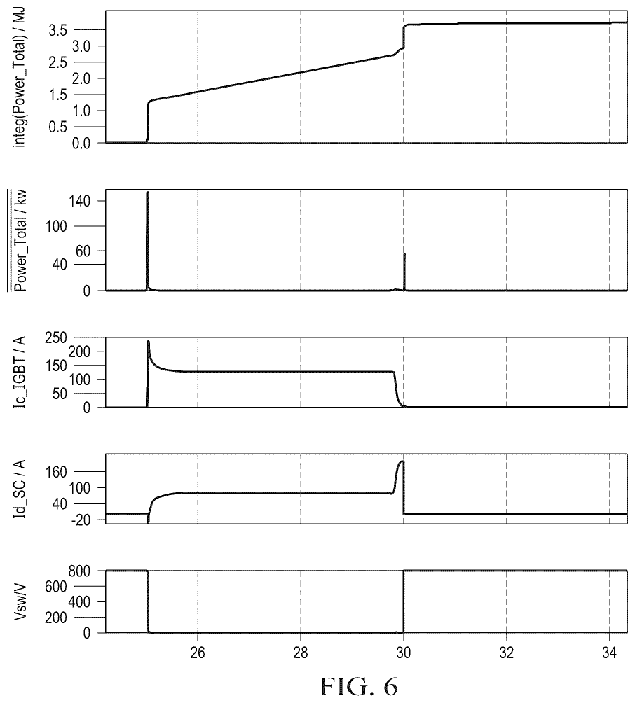

FIG. 6 is a simulation for an energy loss of an apparatus, in an example. The energy loss over an entire switching cycle of the hybrid power switching circuitry may be calculated according to the following equation:

$${\int }_{{t}_{0}}^{{t}_{pd}} {v}_{ce / ds} \times ( {i}_{c} + {i}_{d} ) dt$$

where V_{ce/ds} is the voltage of collector emitter to drain source of the hybrid power switching circuitry, i_{c} is the collector current of the silicon device and i_{d} is the drain current of the WBG device. As illustrated, the energy loss calculation includes turning on and off IV overlap loss as well as conduction loss, thereby improving efficiency.

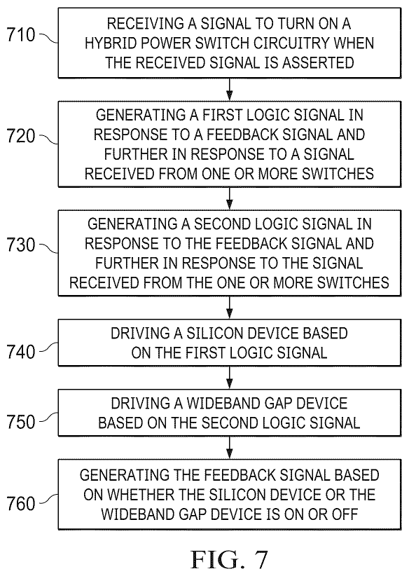

FIG. 7 is a flowchart illustrating operation of an apparatus with a gate driver for hybrid power switches, in an example. At step 710, a signal is received to turn on a hybrid power switch circuitry on when the received signal is asserted, e.g., high. At step 720, a first logic signal is generated in response to a feedback signal and further in response to a signal received from one or more switches (e.g., programmable switches). At step 730, a second logic signal is generated in response to the feedback signal and further in response to the signal received from the one or more switches. At step 740, a silicon device is driven based on the first logic signal. At step 750, a wide bandgap device is driven based on the second logic signal. At step 760, the feedback signal is generated based on whether the silicon device or the wide bandgap device is on or off.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Modifications are possible in the described embodiments, and other embodiments are possible, within the scope of the claims.

What is claimed is:

1. An apparatus comprising:
one or more programmable switches that after programming turn on a first device and a second device within a hybrid power switch circuitry based on a selected ratio of the first device to the second device and further when a received signal to turn on the hybrid power switch circuitry is asserted, wherein the first device is a device with a first type and wherein the second device is a device with a second type;
a logic circuitry coupled to the one or more programmable switches that generates a logic signal to turn a driver circuitry on or off, wherein the logic signal is generated based on a signal received from the one or more programmable switches and further based on a detection signal received from a detection circuitry;
a driver circuitry coupled to the logic circuitry, wherein the driver circuitry generates a driving signal to the hybrid power switch circuitry and the detection circuitry based on the logic signal;
the hybrid power switch circuitry that includes the first device and the second device, wherein the hybrid power switch circuitry receives the driving signal that controls a timing of turning the first device and the second device on and off; and
the detection circuitry that receives a feedback signal associated with the hybrid power switch circuitry, wherein the detection circuitry detects whether the second device is on or off and further whether the first device is on or off, and wherein the detection circuitry generates the detection signal to the logic circuitry.

2. The apparatus of claim 1, wherein the received signal by the one or more programmable switches is a pulse width modulation signal.

3. The apparatus of claim 2, wherein the pulse width modulation signal is generated by a microcontroller.

4. The apparatus of claim 1, wherein the logic circuitry comprises a first portion that generates a first logic signal to control driving the first device on or off and a second portion that generates a second logic signal to control driving the second device.

5. The apparatus of claim 1, wherein the driver circuitry comprises a first portion that drives the first device and a second portion that drives the second device.

6. The apparatus of claim 1, wherein the selected ratio reflects more first device in comparison to the second device, and wherein the first device is turned on first when the received signal to turn on the hybrid switch circuitry is asserted before turning on the second device, and wherein the second device remains on when the first device is turning off and wherein the second device is turned off after the first device is turned off.

7. The apparatus of claim 6, wherein the detection circuitry comprises a comparator to determine whether the first device is on and wherein the detection circuitry generates the feedback signal to turn on the second device in response to determining that the first device is on.

8. The apparatus of claim 6, wherein the detection circuitry comprises a comparator to determine whether the first device is off and wherein the detection circuitry generates the feedback signal to turn off the second device in response to determining that the first device is off.

9. The apparatus of claim 1, wherein the second device is a wide bandgap device that includes a wide bandgap field effect transistor (FET) switch and wherein the first device is a silicon device that includes a silicon FET switch.

10. The apparatus of claim 1, wherein the detection circuitry comprises a comparator.

11. An apparatus comprising:
one or more programmable switches that after programming turn on a wide bandgap device and a silicon device within a hybrid power switch circuitry based on a selected ratio of the silicon device to the wide bandgap device and further when a received signal to turn on the hybrid power switch circuitry is asserted;
a first logic circuit coupled to the one or more programmable switches, wherein the first logic circuit generates a first logic signal;
a first driving circuit coupled to the first logic circuit to receive the first logic signal and in response thereto drive the silicon device of the hybrid power switch circuitry;
a second logic circuit coupled to the one or more programmable switches, wherein the second logic circuit generates a second logic signal;
a second driving circuit coupled to the second logic circuit to receive the second logic signal and in response thereto drive the wide bandgap device of the hybrid power switch circuitry; and
a feedback circuitry that receives a feedback signal associated with the hybrid power switch circuitry, wherein the feedback circuitry generates a feedback signal based on an on/off status of the silicon device or the wide bandgap device, wherein the feedback circuitry sends the feedback signal to the first logic circuit and the second logic circuit,
wherein the first logic circuit generates the first logic signal based on the feedback signal and further based on a signal received from the one or more programmable switches,
wherein the second logic circuit generates the second logic signal based on the feedback signal and further based on the signal received from the one or more programmable switches.

12. The apparatus of claim 11, wherein the received signal by the one or more programmable switches is a pulse width modulation signal.

13. The apparatus of claim 12, wherein the pulse width modulation signal is generated by a microcontroller.

14. The apparatus of claim 11, wherein the selected ratio reflects more silicon device in comparison to the wide bandgap device, and wherein the silicon device is turned on first when the received signal to turn on the hybrid switch circuitry is asserted before turning on the wide bandgap device, and wherein the wide bandgap device remains on when the silicon device is turning off and wherein the wide bandgap device is turned off after the silicon device is turned off.

15. The apparatus of claim 14, wherein the feedback circuitry comprises a comparator to determine whether the silicon device is on and wherein the feedback circuitry generates the feedback signal to turn on the wide bandgap device in response to determining that the silicon device is on.

16. The apparatus of claim 14, wherein the feedback circuitry comprises a comparator to determine whether the silicon device is off and wherein the feedback circuitry generates the feedback signal to turn off the wide bandgap device in response to determining that the silicon device is off.

17. A method comprising:
receiving a signal to turn on a hybrid power switch circuitry when the received signal is asserted;
generating a first logic signal in response to a feedback signal and further in response to a signal received from one or more switches;
generating a second logic signal in response to the feedback signal and further in response to the signal received from the one or more switches;
driving a silicon device based on the first logic signal;
driving a wide bandgap device based on the second logic signal; and
generating the feedback signal based on whether the silicon device or the wide bandgap device is on or off.

18. The method of claim 17 wherein generating the feedback signal comprises comparing a voltage at a gate of the silicon device to a threshold voltage that turns on the silicon device to determine whether the silicon device is turned off or comparing a voltage at a gate of the wide bandgap device to a threshold voltage that turns on the wide bandgap device to determine whether the wide bandgap device is turned off.

19. The method of claim 17 wherein generating the feedback signal comprises comparing a voltage output of the silicon device to a ground to determine whether the silicon device is turned on or comparing a voltage output of the wide bandgap device to determine whether the wide bandgap device is turned on.

20. The method of claim 17 further comprising programming the one or more switches according to ratio of the silicon device to the wide bandgap device within the hybrid power switch circuitry.

21. The method of claim 17 further comprising controlling a timing of turning the wide bandgap device and silicon device on and off based on a positioning of the one or more switches and further based on the signal received to turn the hybrid power switch circuitry on or off.
